(19) United States
(12) Patent Application Publication
(10) Pub. No.: US 2019/0324086 A1
(43) Pub. Date: Oct. 24, 2019

(54) Battery Leakage Current Check Method, Apparatus, And Circuit

(71) Applicant: HUAWEI TECHNOLOGIES CO., LTD., Shenzhen, Guangdong (CN)

(72) Inventors: Wenchao YU, Shanghai (CN); Chong WEN, Shanghai (CN); Hui WANG, Shanghai (CN); Jianjun XU, Shanghai (CN); Kangjie CHAO, Shanghai (CN); Huogen KUANG, Shanghai (CN)

(21) Appl. No.: 16/474,867

(22) PCT Filed: Feb. 28, 2017
(86) PCT No.: PCT/CN2017/075197

§ 371 Date: Jun. 28, 2019

(30) Foreign Application Priority Data
Dec. 30, 2016 (CN) 201611264805.2

(51) Int. Cl. G01R 31/36; G01R 31/02; H01M 10/04; H01M 10/48; H01M 10/42

(52) U.S. Cl. CPC G01R 31/36; G01R 31/024; H01M 10/4285; H01M 10/48; H01M 10/04

(57) ABSTRACT

Embodiments of this application disclose a battery leakage current check method, apparatus, and circuit, and relate to the battery field, so as to check for a leakage current inside a battery. The battery leakage current check method includes: when a power adapter supplies power to an electronic device, controlling the battery to stop supplying power to the electronic device; obtaining a voltage parameter and a duration parameter, where the voltage parameter is a difference between voltages of the battery at two different moments, and the duration parameter is duration between the two different moments; and determining, based on the voltage parameter and the duration parameter, whether a leakage parameter of the battery meets a preset condition. The embodiments of this application are applied to battery leakage current check.

This application claims priority to Chinese Patent Application No. 201611264805.2, filed with the Chinese Patent Office on Dec. 30, 2016 and entitled “BATTERY SAFETY CHECK METHOD”, which is incorporated herein by reference in its entirety.

### TECHNICAL FIELD

This application relates to the battery field, and in particular, to a battery leakage current check method, apparatus, and circuit.

### BACKGROUND

Currently, battery safety has become an important factor that affects safety of an electronic device such as a mobile phone, and the battery safety has become a focus of mobile phone manufacturers. In the prior art, battery over-charge, over-discharge, over-temperature, and the like are checked by detecting a charging/discharging voltage, a charging/discharging current, and the like of a battery. However, there is hardly any proper solution for checking for a leakage current inside the battery.

### SUMMARY

Embodiments of this application provide a battery leakage current check method, apparatus, and circuit, so as to check for a leakage current inside a battery.

To achieve the foregoing objective, the following technical solutions are used in the embodiments of this application.

According to a first aspect, some embodiment of this application provides a battery leakage current check method, wherein a battery is installed in an electronic device and is configured to supply power to the electronic device, and the method comprises: controlling the battery to stop supplying power to the electronic device when a power adapter supplies power to the electronic device; obtaining a voltage parameter and a time duration parameter, wherein the voltage parameter is a difference between voltages of the battery at two different time moments, and the time duration parameter is a duration between the two different time moments; and then determining, based on the voltage parameter and the time duration parameter, whether a leakage parameter of the battery meets a preset condition. According to the battery leakage current check method provided in this embodiment of this application, when the battery stops supplying external power, it is determined, based on a voltage drop between a positive electrode and a negative electrode of the battery after a time period and the time period, whether the leakage parameter of the battery meets the preset condition, to check for a leakage current in the battery and prevent the battery from being faulty, for example, catching fire, due to an excessively high leakage current.

In a possible design, the determining, based on the voltage parameter and the time duration parameter, whether a leakage parameter of the battery meets a preset condition comprises: determining whether a ratio of the voltage parameter to the time duration parameter is less than a preset threshold; and determining that the leakage parameter of the battery meets the preset condition when the ratio of the voltage parameter to the time duration parameter is less than the preset threshold. The design provides a manner of determining whether the leakage parameter of the battery meets the preset condition.

In a possible design, the method further includes: controlling the batter to supply power to the electronic device when the power adapter stops supplying power to the electronic device. The design provides uninterrupted power supply to the electronic device.

In a possible design, the method further includes: outputting prompt information when determining that the leakage parameter of the battery does not meet the preset condition. According to the design, it is convenient to prompt a user in time that the battery may be faulty, so as to ensure use safety by avoiding a fault such as battery fire.

In a possible design, the prompt information includes at least one of the following information: sound information, text information, image information, vibration information, or light information. The design specifically discloses a possible implementation of the prompt information.

In a possible design, the method further includes: sending the leakage parameter to a server when determining that the leakage parameter of the battery does not meet the preset condition. According to the design, it may be convenient for a manufacturer of the electronic device to collect fault information of the electronic device, so as to analyze a fault cause and improve product performance.

In a possible design, when the power adapter stops supplying power to the electronic device, battery leakage current check may be stopped or continue. The design provides a more flexible condition for ending the battery leakage current check.

In a possible design, a condition for triggering the battery leakage current check method includes but is not limited to: after battery charging is completed and the battery is full of electricity, or during battery charging; when it is determined that the electronic device enters a standby state if a user has no operation at a current time or for a long time; when the power adapter is connected to the electronic device and supplies power to the electronic device; when a user enters, by using a user interface (user interface, UI), a command to start to perform battery leakage current check; or at periodic intervals, such as a week, a month, or a year. The design provides a more flexible opportunity of starting to perform battery leakage current check.

According to a second aspect, some embodiment of this application provides a battery leakage current check apparatus, where a to-be-checked battery is installed in an electronic device and is configured to supply power to the electronic device, and the battery leakage current check apparatus includes: a control unit, configured to: control the battery to stop supplying power to the electronic device when a power adapter supplies power to the electronic device; an obtaining unit, configured to obtain a voltage parameter and a time duration parameter, wherein the voltage parameter is a difference between voltages of the battery at two different time moments, and the time duration parameter is a duration between the two different time moments; and a determining unit, configured to determine, based on the voltage parameter and the time duration parameter, whether a leakage parameter of the battery meets a preset condition.

According to the battery leakage current check apparatus provided in this embodiment of this application, when the battery stops supplying external power, it is determined, based on a voltage drop between a positive electrode and a negative electrode of the battery after a time period and the time period, whether the leakage parameter of the battery meets the preset condition, to check for a leakage current in the battery and prevent the battery from being faulty, for example, catching fire, due to an excessively high leakage current. Based on a same inventive concept, for a principle in which the apparatus resolves a problem and a beneficial effect, refer to the first aspect, the possible method implementations of the first aspect, and the brought beneficial effects. Therefore, for implementation of the apparatus, refer to the first aspect and the possible method implementations of the first aspect. Details are not repeatedly described herein.

According to a third aspect, some embodiment of this application provides a battery leakage current check apparatus, including a processor, a memory, a bus, and a communications interface, where the memory is configured to store a computer execution instruction; the processor is connected to the memory by using the bus; and when the battery leakage current check apparatus runs, the processor executes the computer execution instruction stored in the memory, so that the network device performs the battery leakage current check method according to any one of the first aspect and the possible method implementations of the first aspect. Based on a same inventive concept, the processor invokes the instruction stored in the memory to implement the solutions in the method designs of the first aspect. For an implementation in which the apparatus resolves a problem and a beneficial effect, refer to the first aspect and the possible method implementations of the first aspect, and the beneficial effects. Therefore, for implementation of the terminal, refer to the implementations of the method. Details are not repeatedly described herein.

According to a fourth aspect, some embodiment of this application provides a computer storage medium, including an instruction, where when the computer storage medium runs on a computer, the computer performs the battery leakage current check method according to the first aspect.

According to a fifth aspect, some embodiment of this application provides a computer program product including an instruction, where when the computer program product runs on a computer, the computer performs the battery leakage current check method according to the first aspect.

According to a sixth aspect, some embodiment of this application provides a battery leakage current check circuit, disposed in an electronic device, where the circuit includes an electricity meter, a battery, a first switch, a charging chip, and a controller, where the electricity meter is electrically connected to the battery and the controller, and the electricity meter is configured to: obtain a voltage of the battery, and send the obtained battery voltage to the controller; the charging chip is electrically connected to load of the electronic device and the battery, and the charging chip is electrically connected to load of the electronic device and the battery, and the charging chip is configured to receive power supply from a power adapter, and supply power to the load and charge the battery; the first switch is electrically connected to the charging chip, the battery, and the load; and when the first switch is turned on, the battery is electrically connected to the charging chip, and the battery is electrically connected to the load; and when the first switch is turned off, the battery is electrically disconnected from the charging chip, and the battery is electrically disconnected from the load; the controller controls the first switch turned off when the power adapter supplies power to the load using the charging chip; obtains a voltage parameter and a time duration parameter when the first switch is turned off; and determines, based on the voltage parameter and the time duration parameter, whether a leakage parameter of the battery meets a preset condition, wherein the voltage parameter is a difference between voltages of the battery at two different time moments, and the time duration parameter is duration between the two different time moments. According to the battery leakage current check circuit provided in this embodiment of this application, when the battery stops supplying external power, it is determined, based on a voltage drop between a positive electrode and a negative electrode of the battery after a time period and the time period, whether the leakage parameter of the battery meets the preset condition, to check for a leakage current in the battery and prevent the battery from being faulty, for example, catching fire, due to an excessively high leakage current. Based on a same inventive concept, for a principle in which the circuit resolves a problem and a beneficial effect, refer to the first aspect, the possible method implementations of the first aspect, and the brought beneficial effects. Therefore, for implementation of the circuit, refer to the first aspect and the possible method implementations of the first aspect. Details are not repeatedly described herein.

In addition, for a technical effect brought by any one of the design manners in the third aspect to the fifth aspect, refer to the technical effects brought by the different design manners in the first aspect. Details are not repeatedly described herein.

### BRIEF DESCRIPTION OF DRAWINGS

To describe the technical solutions in the embodiments of this application more clearly, the following briefly describes the accompanying drawings required for describing the embodiments or the prior art.

FIG. 1 is a schematic structural diagram of an electronic device according to some embodiment of this application;

FIG. 2 is a schematic structural diagram of a battery leakage current check circuit according to some embodiment of this application;

FIG. 3 is a schematic structural diagram of another battery leakage current check circuit according to some embodiment of this application;

FIG. 4 is a schematic structural diagram of still another battery leakage current check circuit according to some embodiment of this application;

FIG. 5 is a schematic structural diagram of a battery leakage current check circuit in which a battery supplies power to load according to some embodiment of this application;

FIG. 6 is a schematic flowchart of a battery leakage current check method according to some embodiment of this application;

FIG. 7 is a schematic structural diagram of a battery leakage current check circuit for battery leakage current check according to some embodiment of this application;

FIG. 8 is a schematic flowchart of another battery leakage current check method according to some embodiment of this application;

FIG. 9 is a schematic flowchart of still another battery leakage current check method according to some embodiment of this application;

FIG. 10 is a schematic diagram of prompt information being image information according to some embodiment of this application;

FIG. 11 is another schematic diagram of prompt information being image information according to some embodiment of this application;

FIG. 12 is a schematic structural diagram of a battery leakage current check apparatus according to some embodiment of this application;

FIG. 13 is a schematic structural diagram of another battery leakage current check apparatus according to some embodiment of this application; and

FIG. 14 is a schematic structural diagram of still another battery leakage current check apparatus according to some embodiment of this application.

### DESCRIPTION OF EMBODIMENTS

The following describes the embodiments of this application with reference to the accompanying drawings.

A leakage current described in the embodiments of this application indicates self discharge performed by a battery that is in a natural placement state and that is not connected to an external power consumption circuit. As time elapses, a voltage difference between a positive electrode and a negative electrode of the battery increasingly decreases. A battery leakage current check method, apparatus, and circuit provided in the embodiments of this application are used to determine whether leakage current is serious by using a voltage drop between a positive electrode and a negative electrode of a battery.

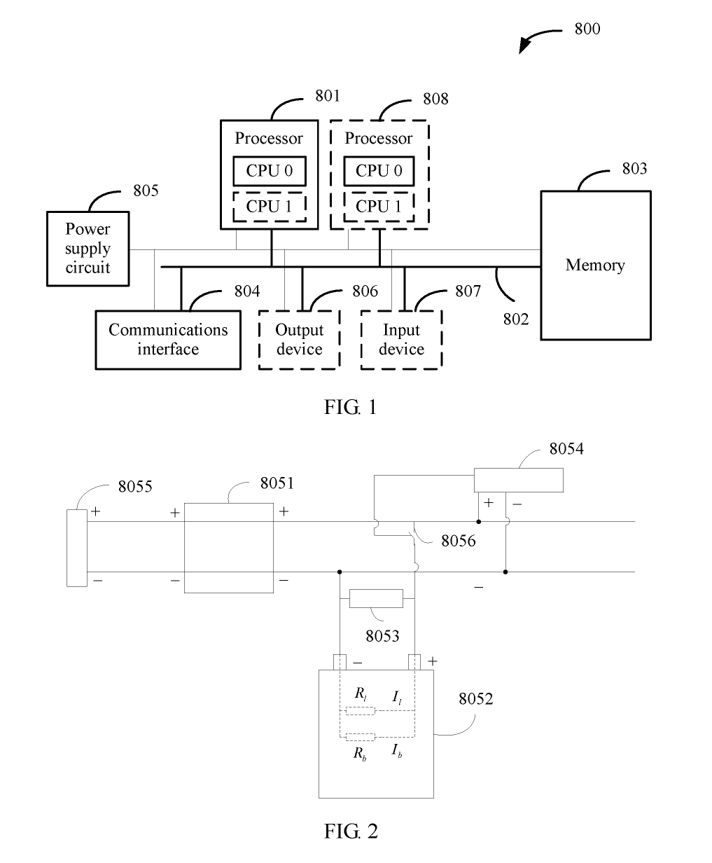

As shown in FIG. 1, FIG. 1 is a schematic structural diagram of hardware of an electronic device 800 according to some embodiment of this application. The electronic device 800 includes at least one processor 801, a communications bus 802, a memory 803, at least one communications interface 804, and a battery leakage current check circuit 805.

The processor 801 may be a general-purpose central processing unit (central processing unit, CPU), a microprocessor, an application-specific integrated circuit (application-specific integrated circuit, ASIC), or one or more integrated circuits configured to control program execution of the solution in this application.

The communications bus 802 may include a path on which information is transmitted between the foregoing components.

The memory 803 may be a read-only memory (read-only memory, ROM) or another type of static storage device that may store static information and instructions, a random access memory (random access memory, RAM) or another type of dynamic storage device that may store information and instructions; or may be an electrically erasable programmable read-only memory (electrically erasable programmable read-only memory, EEPROM), a compact disc read-only memory (compact disc read-only memory, CD-ROM) or other compact disc storage, optical disc storage (including a compact disc, a laser disc, an optical disc, a digital versatile disc, a Blu-ray disc, and the like), a magnetic disk storage medium or another magnetic storage device, or any other medium that can be used to carry or store expected program code that has an instruction or data structure form and that can be accessed by a computer. However, this is not limited herein. The memory may be a separate memory and is connected to the processor by using the bus, or the memory may be integrated with the processor.

The memory 803 is configured to store application program code that executes the solution in this application, and the processor 801 controls execution of the solution in this application. The processor 801 is configured to execute the application program code stored in the memory 803, so as to implement the battery leakage current check method.

The communications interface 804, which uses any apparatus such as a transceiver, is configured to communicate with another device or communications network, such as Ethernet, a radio access network (radio access network, RAN), or a wireless local area network (wireless local area networks, WLAN).

The battery leakage current check circuit 805 includes a power source such as a battery, which is configured to provide a normal working voltage for load of the electronic device 800.

In specific implementation, in some embodiment, the processor 801 may include one or more CPUs, such as a CPU 0 and a CPU 1 in FIG. 1.

In specific implementation, in some embodiment, the electronic device 800 may include a plurality of processors, such as a processor 801 and a processor 808 in FIG. 1. Each of these processors may be a single-core (single-CPU) processor or a multi-core (multi-CPU) processor. The processor herein may be one or more devices, circuits, and/or processing cores configured to process data (for example, a computer program instruction).

In specific implementation, in some embodiment, the electronic device 800 may further include an output device 806 and an input device 807. The output device 806 communicates with the processor 801, and may display information in a plurality of manners. For example, the output device 806 may be a liquid crystal display (liquid crystal display, LCD), a light emitting diode (light emitting diode, LED) display device, a cathode ray tube (cathode ray tube, CRT) display device, a projector (projector), or the like. The input device 807 communicates with the processor 801, and may receive input of a user in a plurality of manners. For example, the input device 807 may be a mouse, a keyboard, a touchscreen device, a sensor device, or the like.

The electronic device 800 may be a general-purpose electronic device or a dedicated electronic device. In specific implementation, the electronic device 800 may be a desktop computer, a portable computer, a network server, a personal digital assistant (personal digital assistant, PDA), a mobile phone, a tablet computer, a wireless terminal device, a communications device, an embedded device, or a device with a structure similar to that in FIG. 1. A type of the electronic device 800 is not limited in this embodiment of this application.

Referring to FIG. 2, some embodiment of this application provides a battery leakage current check circuit. The circuit includes a charging chip 8051, a battery 8052, an electricity meter 8053, a controller 8054, a power adapter 8055, and a first switch 8056.

The electricity meter 8053 is electrically connected to the battery 8052 and the controller 8054. The electricity meter 8053 is configured to: obtain a voltage of the battery 8052, and send the obtained battery voltage to the controller 8054.

The charging chip 8051 is electrically connected to load (not shown in the figure) of an electronic device, and the charging chip 8051 is electrically connected to the battery 8052. The charging chip 8051 is configured to receive power supply from the power adapter 8055, so as to supply power to the load and charge the battery 8052 at the same time.

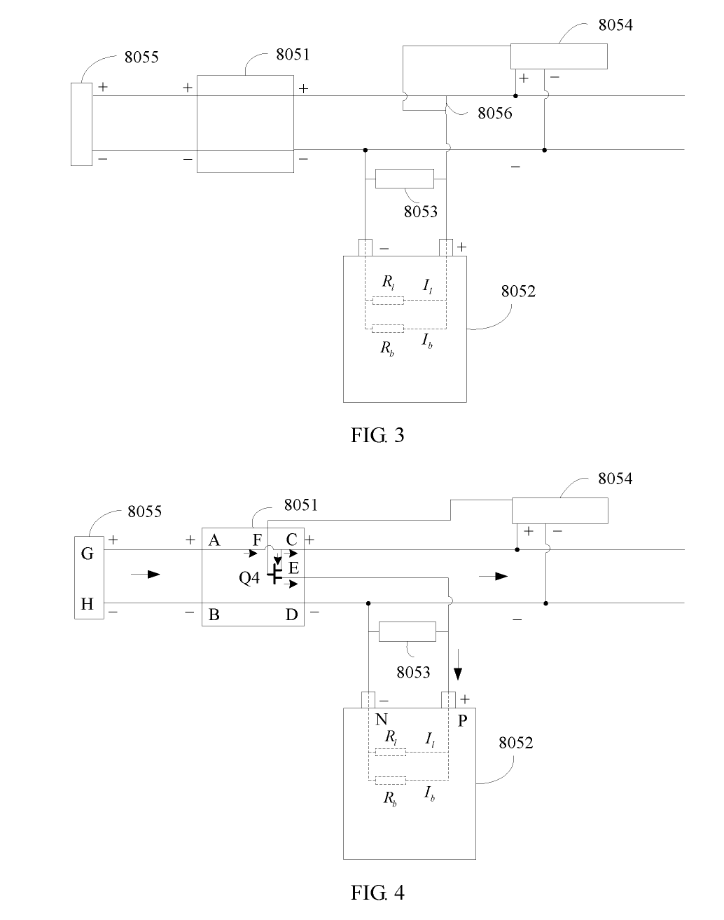

The first switch 8056 is electrically connected to the charging chip 8051, the battery 8052, and the load. Referring to FIG. 2, when the first switch 8056 is turned off, the battery 8052 is electrically disconnected from the charging chip 8051 and the load. Referring to FIG. 3, when the first switch 8056 is turned on, the battery 8052 is electrically connected to the charging chip 8051 and the load. When the power adapter 8055 is electrically disconnected from the charging chip 8051, the battery 8052 is enabled to electrically connect to the load of the electronic device, so that the battery 8052 supplies power to the load of the electronic device. When the power adapter 8055 is electrically connected to the charging chip 8051, the power adapter 8055 may use the charging chip 8051 to supply power to the load of the electronic device and charge the battery 8052 at the same time.

FIG. 2 and FIG. 3 further show an equivalent battery internal resistance R_{b} and a leakage current resistance Rₗ. The internal resistance R_{b} is used to indicate that when the battery 8052 is charged or discharges, heat is generated and specific electrical energy is consumed; and the battery 8052 is equivalent to a resistance that generates heat. A current that flows is I_{b}. The leakage current resistance Rₗ is a resistance corresponding to a generated leakage current. A current that flows is Iₗ.

It should be noted that, the foregoing discloses an example of the first switch 8056 according to function division only. A person skilled in the art may figure out that another switch (such as a metal oxide semiconductor (metal oxide semiconductor, MOS) transistor) having a similar function is also applicable to the protection scope of this application.

For example, referring to FIG. 4, FIG. 4 is a schematic diagram of an example of a battery leakage current check circuit 805. The battery leakage current check circuit includes a charging chip 8051, a battery 8052, an electricity meter 8053, a controller 8054, and a power adapter 8055. The charging chip 8051 includes a charging positive voltage pin A, a charging ground pin B, a power supply positive voltage pin C, a power supply ground pin D, a battery pin E, and a control pin F. The battery 8052 includes a positive electrode P and a negative electrode N.

A MOS transistor switch Q4 (the MOS transistor switch Q4 herein is equivalent to the first switch 8056) is built in the charging chip 8051. A gate electrode of the MOS transistor switch Q4 is electrically connected to a control end of the controller 8054 by using the control pin F. A source electrode of the MOS transistor switch Q4 is electrically connected to the positive electrode P of the battery 8052 by using the battery pin E. A drain electrode of the MOS transistor switch Q4 is electrically connected to the charging positive voltage pin A and the power supply positive voltage pin C. The charging positive voltage pin A of the charging chip 8051 is electrically connected to a positive voltage output end G of the power adapter 8055, the charging ground pin B of the charging chip 8051 is electrically connected to a ground output end H of the power adapter 8055, and the charging ground pin B is electrically connected to the power supply ground pin D. The power supply positive voltage pin C and the power supply ground pin D of the charging chip 8051 are electrically connected to load (not shown in the figure) inside an electronic device to supply power to the load.

When the controller 8054 provides a high level for the gate electrode of the MOS transistor switch Q4, the drain electrode and the source electrode of the MOS transistor switch Q4 are conducted, so that the battery 8052 and the charging chip 8051 are electrically connected. Referring to FIG. 4, when the power adapter 8055 is connected to the charging positive voltage pin A and the charging ground pin B, the power adapter 8055 supplies power to the charging chip 8051. After transferring the power, the charging chip 8051 may supply power to the load inside the electronic device, and may charge the battery 8052 by using the battery pin E and the power supply ground pin D at the same time. An arrow in the figure is a current direction.

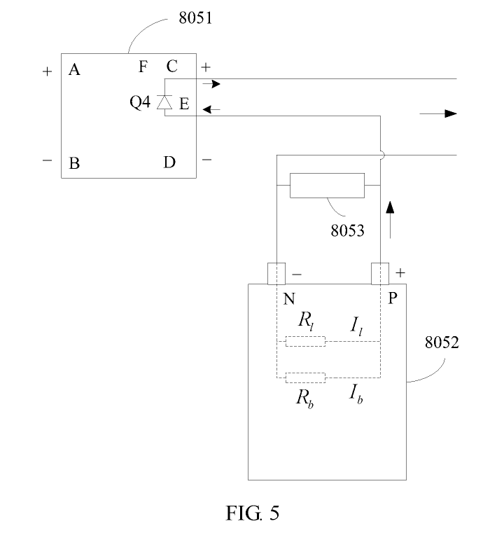

Referring to FIG. 5, when the power adapter is disconnected from the pin A and the charging ground pin B, the MOS transistor switch Q4 is equivalent to a diode. Because a voltage of the positive electrode P of the battery 8052 is greater than a cutoff voltage of the diode, the diode is automatically conducted, so that the power supply positive voltage pin C and the battery pin E are conducted, and the battery 8052 supplies power to the load inside the electronic device, so as to implement seamless power supply switching. An arrow in the figure is a current direction. It should be noted that, the drain electrode and the source electrode of the MOS transistor switch Q4 are conducted because a forward voltage is greater than a cutoff voltage, and therefore there is still a relatively large current loss on the MOS transistor switch Q4 during power supply switching. The controller 8054 needs to provide a high level for the gate electrode of the MOS transistor switch Q4 again, and then the source electrode and the drain electrode of the MOS transistor switch Q4 are naturally conducted. In this case, there is a relatively small current loss on the MOS transistor switch Q4.

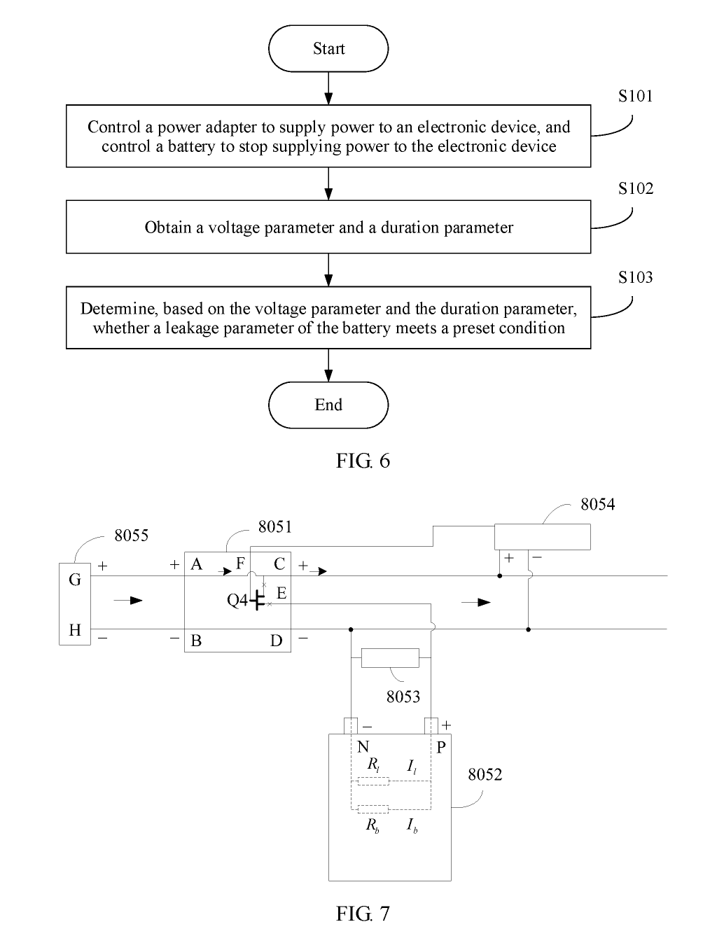

Some embodiment of this application provides a battery leakage current check method, which may be performed by the controller 8054 described above. Referring to FIG. 6, the method includes steps S101 to S103.

S101. Control a power adapter to supply power to an electronic device, and control a battery to stop supplying power to the electronic device.

To prevent the electronic device from being shut down because of power failure, a power adapter 8055 needs to supply power to load of the electronic device by using a charging chip 8051. In addition, a battery 8052 needs to be electrically disconnected from the charging chip 8051 and the load, so as to electrically disconnect the battery 8052 from the power adapter 8055 and the load of the electronic device, so that the battery is in a natural unloaded state. Referring to FIG. 2, the controller 8054 controls a first switch 8056 to be turned off. Alternatively, referring to FIG. 7, the controller 8054 outputs a low level to a gate electrode of a MOS transistor switch Q4, so that a drain electrode and a source electrode of the MOS transistor switch Q4 are cut off. An arrow in the figure is a current direction.

It should be noted that a condition for triggering battery leakage current check includes but is not limited to: after battery charging is completed and the battery is full of electricity, or during battery charging; when it is determined that the electronic device enters a standby state if a user has no operation at a current time or for a long time; when the power adapter is connected to the electronic device and supplies power to the electronic device; when a user enters, by using a user interface (user interface, UI), a command to start to perform battery leakage current check; or at periodic intervals, such as a week, a month, or a year.

When the battery is full of electricity, a voltage difference between a positive electrode and a negative electrode of the battery may theoretically reach a rated voltage of the battery, such as 4.2 V or 4.35 V. However, because all batteries have self discharge at different degrees, and discharge of a battery increases as time passes, a voltage difference between a positive electrode and a negative electrode of the battery decreases. As a result, a rated voltage of the battery cannot be reached.

S102. Obtain a voltage parameter and a duration parameter, where the voltage parameter is a difference between voltages of the battery at two different moments, and the duration parameter is duration between the two different moments.

For example, a first voltage of the battery 8052 may be measured at a first moment by using an electricity meter 8053, and a second voltage of the battery 8052 may be measured at a second moment by using the electricity meter 8053. In this case, the voltage parameter is a difference between the first voltage and the second voltage, and the duration parameter is duration from the first moment to the second moment. In other words, the duration parameter is a time difference between the first moment and the second moment. Alternatively, for example, the voltage parameter and the duration parameter may be directly obtained.

S103. Determine, based on the voltage parameter and the duration parameter, whether a leakage parameter of the battery meets a preset condition.

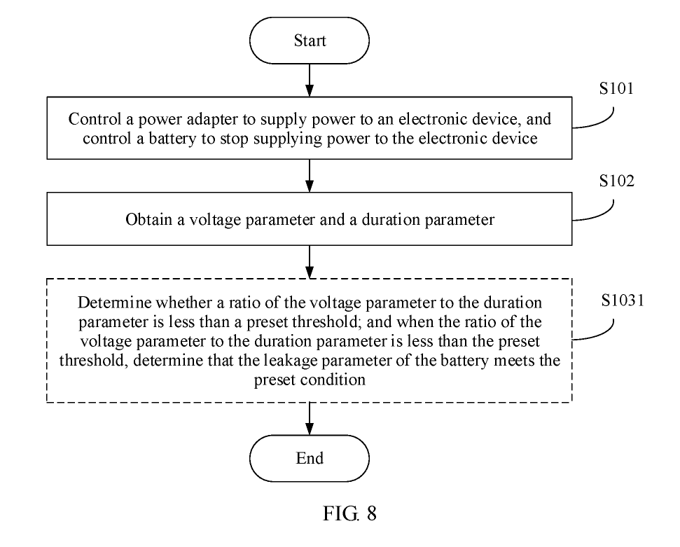

That a leakage parameter of the battery meets a preset condition means that a leakage current in the battery is relatively low, that is, within a normal range. In this case, the battery works in a normal state. That a leakage parameter of the battery does not meet a preset condition means that a leakage current in the battery is relatively high, that is, beyond a normal range. In this case, the battery works in an abnormal state. If the leakage current inside the battery is relatively high, correspondingly, a time required for a unit voltage drop of the battery is less than a preset threshold, or a voltage drop of the battery within a unit time exceeds a preset threshold. Therefore, referring to FIG. 8, step S103 may specifically include step S1031:

S1031. Determine whether a ratio of the voltage parameter to the duration parameter is less than a preset threshold; and when the ratio of the voltage parameter to the duration parameter is less than the preset threshold, determine that the leakage parameter of the battery meets the preset condition.

The preset threshold may be set based on an actual situation.

For example, it is assumed that the preset threshold is 10 mV/hour (when a current of about 30 mA is consumed, a corresponding leakage current is about 30 mA). When battery charging is completed (at the first moment), a voltage between the positive electrode and the negative electrode of the battery is measured to obtain the first voltage. An hour later (at the second moment), a voltage between the positive electrode and the negative electrode of the battery is measured to obtain the second voltage. In this case, the voltage parameter is equal to the first voltage minus the second voltage, and the duration parameter is one hour. It is determined whether the ratio of the voltage parameter to the duration parameter is less than the preset threshold. When the ratio of the voltage parameter to the duration parameter is less than 10 mV/hour, it is determined that the leakage parameter of the battery meets the preset condition, and the battery works normally. When the ratio of the voltage parameter to the duration parameter is greater than 10 mV/hour, it is determined that the leakage current in the battery is relatively high, the leakage parameter of the battery does not meet the preset condition, and the battery works abnormally.

According to the battery leakage current check method provided in this embodiment of this application, when the battery stops supplying external power, and no power adapter is connected, it is determined, based on the voltage drop of the battery within the unit time or duration of the unit voltage drop, whether the leakage parameter of the battery meets the preset condition, to check for the leakage current in the battery and prevent the battery from being faulty, for example, catching fire, due to an excessively high leakage current.

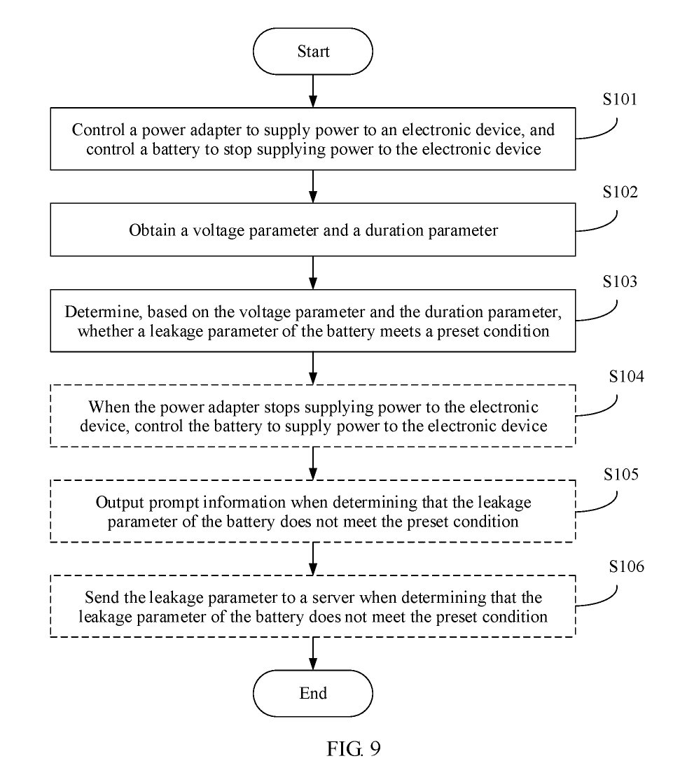

Some embodiment of this application provides another battery leakage current check method. Optionally, referring to FIG. 9, the method further includes step S104:

S104. When the power adapter stops supplying power to the electronic device, supply power to the electronic device by using the battery.

Likewise, this step may ensure uninterrupted power supply to the electronic device. For details, refer to the description of the implementation in which the battery 8052 supplies power to the load of the electronic device in FIG. 3 and FIG. 5. Details are not repeatedly described herein. It should be noted that step S104 may occur at any time in steps S101 to S103. In addition, battery leakage current check may be stopped or continue, except that a check result is not used to determine whether the leakage parameter of the battery meets the preset condition.

Optionally, referring to FIG. 9, the method may further include step S105:

S105. Output prompt information when determining that the leakage parameter of the battery does not meet the preset condition.

Optionally, the prompt information includes at least one of the following information: sound information, text information, image information, vibration information, light information, and the like. For example, a display may be instructed to output the text information, the image information, the light information, and the like. A headset, an earpiece, a loudspeaker, and the like may be instructed to output the sound information. A vibration motor may be instructed to output the vibration information. In addition, when the prompt information is the image information, the text information, the light information, and the like, the prompt information may be displayed in a blinking manner to further emphasize an emergency degree. In this way, it is convenient to prompt a user in time that the battery may be faulty, so as to ensure use safety by avoiding a fault such as battery fire.

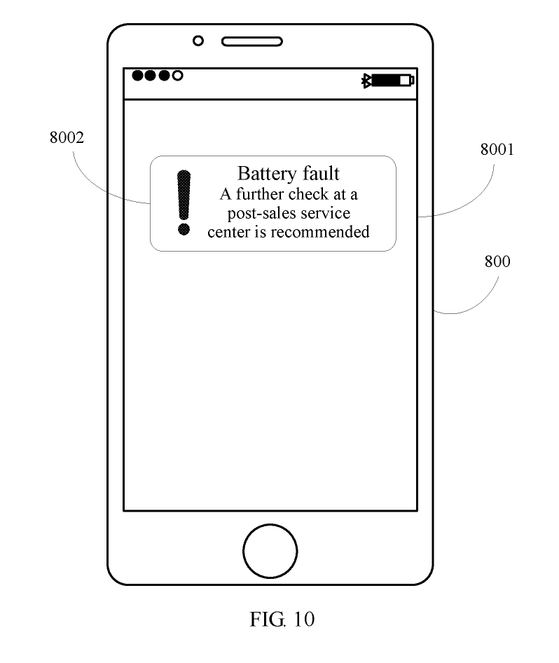

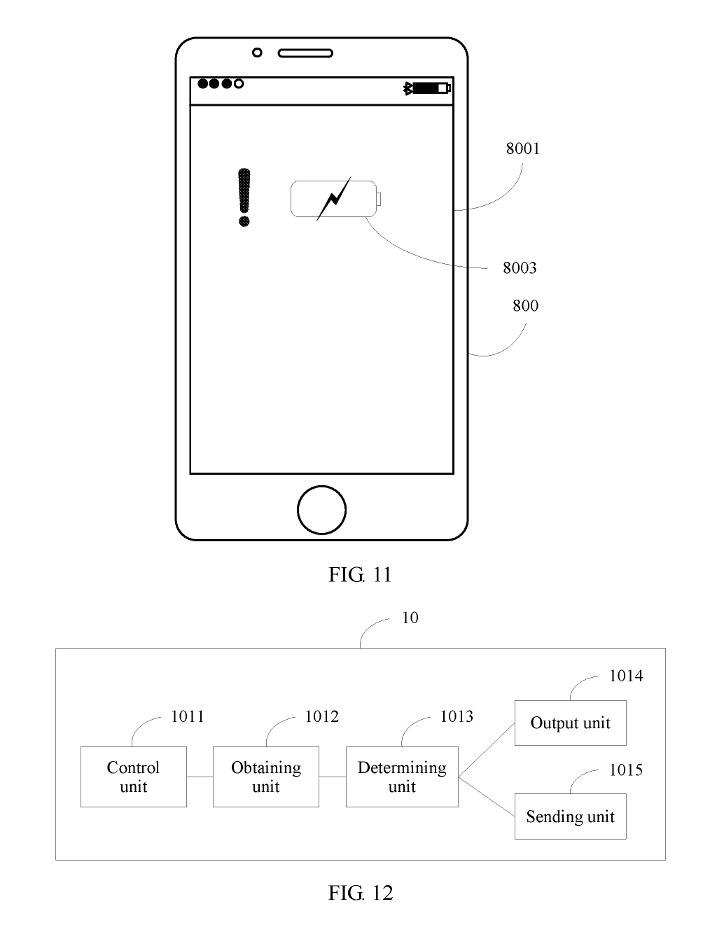

For example, referring to FIG. 10, FIG. 10 shows an example in which the prompt information is image information. A text 8002 is displayed on a display screen 8001 of an electronic device 800, for example, “Battery fault! A further check at a post-sales service center is recommended” may be notified. Referring to FIG. 11, FIG. 11 shows another example in which the prompt information is image information. A battery image 8003 may be displayed on a display screen 8001 of an electronic device 800. In addition, different from a normal battery state during charging, the battery may be displayed in an alarm color such as red. A person skilled in the art may further figure out other image information, and details are not described herein.

Optionally, referring to FIG. 9, the method may further include step S106:

S106. Send the leakage parameter to a server when determining that the leakage parameter of the battery does not meet the preset condition.

The collected leakage parameter may be uploaded in a wired or wireless manner, and the used communication means includes but is not limited to Wireless Fidelity (Wireless-Fidelity, WiFi), Bluetooth (Bluetooth, BT), an infrared ray, a laser, a sound wave, the ZigBee (ZigBee) protocol, and the like. In this way, it may be convenient for a manufacturer of the electronic device to collect fault information of the electronic device, so as to analyze a fault cause and improve product performance.

It should be noted that there is no execution sequence between steps S105 and S106.

Some embodiment of this application provides a battery leakage current check apparatus, configured to perform the foregoing battery leakage current check method. In this embodiment of this application, the battery leakage current check apparatus may be divided into function modules according to the method examples. For example, various function modules corresponding to various functions may be obtained through division, or two or more functions may be integrated into one processing module. The integrated module may be implemented in a form of hardware, or may be implemented in a form of a software functional module. It should be noted that, the module division in this embodiment of this application is an example, is merely logical function division, and may be another division manner in actual implementation.

When various function modules corresponding to various functions are obtained through division, FIG. 12 shows a possible schematic structural diagram of the battery leakage current check apparatus in the foregoing embodiments. A battery leakage current check apparatus 10 includes a control unit 1011, an obtaining unit 1012, a determining unit 1013, an output unit 1014, and a sending unit 1015. The control unit 1011 is configured to support the battery leakage current check apparatus 10 to perform process S101 in FIG. 6, process S101 in FIG. 8, and processes S101 and S104 in FIG. 9. The obtaining unit 1012 is configured to support the battery leakage current check apparatus 10 to perform process S102 in FIG. 6, process S102 in FIG. 8, and process S102 in FIG. 9. The determining unit 1013 is configured to support the battery leakage current check apparatus 10 to perform process S103 in FIG. 6, process S1031 in FIG. 8, and process S103 in FIG. 9. The output unit 1014 is configured to support the battery leakage current check apparatus 10 to perform process S105 in FIG. 9. The sending unit 1015 is configured to support the battery leakage current check apparatus 10 to perform process S106 in FIG. 9. All the related content of the steps used in the method embodiments may be cited in function descriptions of corresponding function modules, and details are not repeatedly described herein.

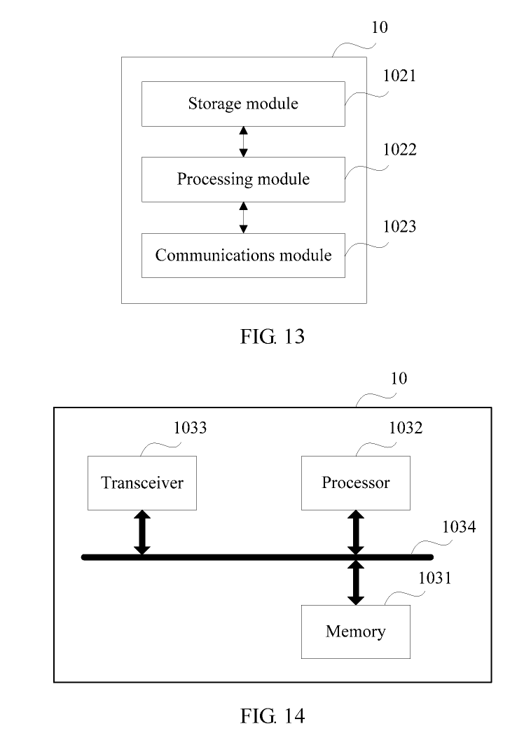

When an integrated unit is used, FIG. 13 shows a possible schematic structural diagram of the battery leakage current check apparatus in the foregoing embodiments. A battery leakage current check apparatus 10 includes a processing module 1022 and a communications module 1023. The processing module 1022 is configured to control and manage an action of the battery leakage current check apparatus 10. For example, the processing module 1022 is configured to support the battery leakage current check apparatus 10 to perform processes S101 to S103 in FIG. 6, processes S101 to S1031 in FIG. 8, and processes S101 to S106 in FIG. 9. The communications module 1023 is configured to support communication between the battery leakage current check apparatus and another entity, for example, communication with a function module or a network entity shown in FIG. 6. The battery leakage current check apparatus 10 may further include a storage module 1021, configured to store program code and data of the battery leakage current check apparatus.

The processing module 1022 may be a processor or a controller, for example, may be a central processing unit (central processing unit, CPU), a general-purpose processor, a digital signal processor (digital signal processor, DSP), an application-specific integrated circuit (application-specific integrated circuit, ASIC), a field programmable gate array (field programmable gate array, FPGA) or another programmable logic device, a transistor logic device, a hardware component, or any combination thereof. The processing module 1022 may implement or execute various examples of logical blocks, modules, and circuits that are described with reference to content disclosed in this application. Alternatively, the processor may be a combination of processors implementing a computing function, for example, a combination of one or more microprocessors, or a combination of a DSP and a microprocessor. The communications module 1023 may be a transceiver, a transceiver circuit, a communications interface, or the like. The storage module 1021 may be a memory.

When the processing module 1022 is a processor, the communications module 1023 is a transceiver, and the storage module 1021 is a memory, the battery leakage current check apparatus in this embodiment of this application may be a battery leakage current check apparatus 10 described below.

Referring to FIG. 14, the battery leakage current check apparatus 10 includes a processor 1032, a transceiver 1033, a memory 1031, and a bus 1034. The transceiver 1033, the processor 1032, and the memory 1031 are interconnected by using the bus 1034. The bus 1034 may be a peripheral component interconnect (peripheral component interconnect, PCI) bus, an extended industry standard architecture (extended industry standard architecture, EISA) bus, or the like. The bus may be classified into an address bus, a data bus, a control bus, and the like. For ease of representation, only one thick line is used to represent the bus in the figure, but this does not mean that there is only one bus or only one type of bus.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1-21. (canceled)

22. A battery leakage current check method, wherein a battery is installed in an electronic device and is configured to supply power to the electronic device, and the method comprises:
controlling, by the electronic device, the battery to stop supplying power to the electronic device when a power adapter supplies power to the electronic device;
obtaining, by the electronic device, a voltage parameter and a time duration parameter, wherein the voltage parameter is a difference between voltages of the battery at two different time instances, and the time duration parameter is a duration between the two different time instances; and
determining, by the electronic device, based on the voltage parameter and the time duration parameter, whether a leakage parameter of the battery meets a preset condition.

23. The battery leakage current check method of claim 22, wherein the determining, by the electronic device, based on the voltage parameter and the time duration parameter, whether a leakage parameter of the battery meets a preset condition comprises:
determining, by the electronic device, whether a ratio of the voltage parameter to the time duration parameter is less than a preset threshold; and
determining, by the electronic device, that the leakage parameter of the battery meets the preset condition if the ratio of the voltage parameter to the time duration parameter is less than the preset threshold.

24. The battery leakage current check method of claim 22, wherein the method further comprises:
controlling, by the electronic device, the battery to supply power to the electronic device in response to that the power adapter stops supplying power to the electronic device.

25. The battery leakage current check method of claim 22, wherein the method further comprises:
outputting, by the electronic device, prompt information in response to determining that the leakage parameter of the battery does not meet the preset condition.

26. The battery leakage current check method of claim 25, wherein the prompt information comprises at least one of sound information, text information, vibration information, or light information.

27. The battery leakage current check method of claim 25, wherein the prompt information comprises image information.

28. The battery leakage current check method of claim 22, wherein the method further comprises:
sending, by the electronic device, the leakage parameter to a server in response to determining that the leakage parameter of the battery does not meet the preset condition.

29. A battery leakage current check apparatus coupled to a battery installed in an electronic device and configured to supply power to the electronic device, the battery leakage current check apparatus comprising:
at least one processor; and
a non-transitory computer-readable storage medium coupled to the at least one processor and storing programming instructions for execution by the at least one processor, wherein the programming instructions instruct the at least one processor to:
control a battery to stop supplying power to the electronic device when a power adapter supplies power to the electronic device;
obtain a voltage parameter and a time duration parameter, wherein the voltage parameter is a difference between voltages of the battery at two different time instances, and the time duration parameter is a duration between the two different time instances; and
determine, based on the voltage parameter and the time duration parameter, whether a leakage parameter of the battery meets a preset condition.

30. The battery leakage current check apparatus of claim 29, wherein the programming instructions instruct the at least one processor to:
determine whether a ratio of the voltage parameter to the time duration parameter is less than a preset threshold; and
determine that the leakage parameter of the battery meets the preset condition if the ratio of the voltage parameter to the time duration parameter is less than the preset threshold.

31. The battery leakage current check apparatus of claim 29, wherein the programming instructions instruct the at least one processor to:
control the battery to supply power to the electronic device in response to that the power adapter stops supplying power to the electronic device.

32. The battery leakage current check apparatus of claim 29, wherein the programming instructions instruct the at least one processor to: output prompt information in response to determining that the leakage parameter of the battery does not meet the preset condition.

33. The battery leakage current check apparatus of claim 32, wherein the prompt information comprises at least one of sound information, text information, image information, vibration information, or light information.

34. The battery leakage current check apparatus of claim 32, wherein the prompt information comprises image information.

35. The battery leakage current check apparatus of claim 29, wherein the programming instructions instruct the at least one processor to: send the leakage parameter to a server in response to determining that the leakage parameter of the battery does not meet the preset condition.

36. A non-transitory computer readable medium having instructions stored therein, which, when executed by at least one processor, cause the at least one processor to perform operations for checking leakage current of a battery that is installed in an electronic device and is configured to supply power to the electronic device, the operations comprising:
controlling the battery to stop supplying power to the electronic device when a power adapter supplies power to the electronic device;
obtaining a voltage parameter and a time duration parameter, wherein the voltage parameter is a difference between voltages of the battery at two different time instances, and the time duration parameter is a duration between the two different time instances; and
determining, based on the voltage parameter and the time duration parameter, whether a leakage parameter of the battery meets a preset condition.

37. The non-transitory computer readable medium of claim 36, wherein the operations further comprising:
determining whether a ratio of the voltage parameter to the time duration parameter is less than a preset threshold; and
determining that the leakage parameter of the battery meets the preset condition if the ratio of the voltage parameter to the time duration parameter is less than the preset threshold.

38. The non-transitory computer readable medium of claim 36, wherein the operations further comprising:
controlling the battery to supply power to the electronic device in response to that the power adapter stops supplying power to the electronic device.

39. The non-transitory computer readable medium of claim 36, wherein the operations further comprising:
outputting prompt information in response to determining that the leakage parameter of the battery does not meet the preset condition.

40. The non-transitory computer readable medium of claim 39, wherein the prompt information comprises at least one of sound information, text information, image information, vibration information, or light information.

41. The non-transitory computer readable medium of claim 36, wherein the operations further comprising: sending the leakage parameter to a server in response to determining that the leakage parameter of the battery does not meet the preset condition.
